(19) United States
(12) Patent Application Publication
(10) Pub. No.: US 2026/0088058 A1
(43) Pub. Date: Mar. 26, 2026

(54) SEMICONDUCTOR MEMORY DEVICE

(71) Applicant: Kioxia Corporation, Tokyo (JP)

(72) Inventors: Daiki NISHIHARA, Yokkaichi Mie (JP); Hiroyasu SATO, Yokkaichi Mie (JP)

(21) Appl. No.: 19/070,479

(22) Filed: Mar. 4, 2025

(30) Foreign Application Priority Data
Sep. 20, 2024 (JP) 2024-163625

(51) Int. Cl. G11C 5/06; G11C 16/04; G11C 16/14; H10B 43/27; H10B 43/40; H10D 30/69

(52) U.S. Cl. CPC G11C 5/063; G11C 16/0483; G11C 16/14; H10B 43/27; H10B 43/40; H10D 30/691; H10D 30/693

(57) ABSTRACT

A semiconductor memory device includes first and second stacked films, each of which includes a plurality of conductive layers and a plurality of insulating layers alternately stacked one on top of another, a first core insulating film penetrating the stacked film and containing an oxide, a channel semiconductor film around the first core insulating film and penetrating the first stacked film, a tunnel insulating film around the channel semiconductor film and penetrating the first stacked film, and a charge storage film around the tunnel insulating film and penetrating the first stacked film. The first stacked film additionally includes a second core insulating film around the first core insulating film, penetrating the first stacked film and containing a nitride, and a third core insulating film between the channel semiconductor film and the second core insulating film, penetrating the first stacked film, and including an oxide.

### CROSS-REFERENCE TO RELATED APPLICATION(S)

This application is based upon and claims the benefit of priority from Japanese Patent Application No. 2024-163625, filed Sep. 20, 2024, the entire contents of which are incorporated herein by reference.

### FIELD

Embodiments described herein relate generally to a semiconductor memory device.

### BACKGROUND

A large-capacity nonvolatile memory is being developed. This large-capacity nonvolatile memory is capable of low-voltage and low-current operation, high-speed switching, and also, miniaturization and high integration of memory cells.

A large number of metal wirings called bit lines and word lines are arranged in a memory cell array provided in the large-capacity nonvolatile memory. A voltage is applied to the bit line and word line connected to a memory cell, and data is written to the memory cell corresponding to the bit line and word line. A semiconductor memory device in which memory cells are arranged three-dimensionally and which include a stacked film, in which conductive layers and insulating layers serving as word lines are alternately stacked, is proposed.

### BRIEF DESCRIPTION OF THE DRAWINGS

FIG. 1 illustrates a block diagram of a semiconductor memory device according to a first embodiment.

FIG. 2 is an equivalent circuit diagram of the semiconductor memory device according to the first embodiment.

FIG. 3 is a schematic cross-sectional view of a main part of the semiconductor memory device according to the first embodiment.

FIGS. 4-10 are schematic cross-sectional views illustrating a method of manufacturing the semiconductor memory device according to the first embodiment.

FIG. 11 is a schematic cross-sectional view of a main part of a semiconductor memory device according to a second embodiment.

### DETAILED DESCRIPTION

Embodiments provide a semiconductor memory device that is easy to manufacture and capable of high-density recording.

In general, according to one embodiment, there is provided a semiconductor memory device including a first stacked film in which a plurality of first conductive layers and a plurality of first insulating layers are alternately stacked one on top of another in a first direction and extend in a second direction intersecting the first direction and a third direction intersecting the first direction and the second direction, a first core insulating film penetrating the first stacked film in the first direction and containing an oxide, a second core insulating film provided around the first core insulating film, penetrating the first stacked film in the first direction, and including a nitride, a third core insulating film provided around the second core insulating film, penetrating the first stacked film in the first direction, and containing an oxide, a first channel semiconductor film provided around the third core insulating film and penetrating the first stacked film in the first direction, a first tunnel insulating film provided around the first channel semiconductor film and penetrating the first stacked film in the first direction, a first charge storage film provided around the first tunnel insulating film and penetrating the first stacked film in the first direction, a second stacked film in which a plurality of second conductive layers and a plurality of second insulating layers are alternately stacked one on top of another in a first direction and extend in the second and third directions, a fourth core insulating film penetrating the second stacked film in the first direction and containing an oxide, a second channel semiconductor film provided around the fourth core insulating film and penetrating the second stacked film in the first direction, a second tunnel insulating film provided around the second channel semiconductor film and penetrating the second stacked film in the first direction, and a second charge storage film provided around the second tunnel insulating film and penetrating the second stacked film in the first direction.

Hereinafter, embodiments will be described with reference to the drawings. In the drawings, the same or similar parts are denoted by the same or similar reference numerals.

In this specification, in order to indicate the positional relationship of parts and the like, an upward direction in the drawings will be described as “upper” and a downward direction in the drawings will be described as “lower”. In this specification, the concepts of “upper” and “lower” are not necessarily terms that indicate a relationship with the direction of gravity.

### First Embodiment

A semiconductor memory device according to an embodiment includes a first stacked film in which a plurality of first conductive layers and a plurality of first insulating layers are alternately stacked one on top of another in a first direction and extend in a second direction intersecting the first direction and a third direction intersecting the first direction and the second direction, a first core insulating film penetrating the first stacked film in the first direction and containing an oxide, a second core insulating film provided around the first core insulating film, penetrating the first stacked film in the first direction, and including a nitride, a third core insulating film provided around the second core insulating film, penetrating the first stacked film in the first direction, and containing an oxide, a first channel semiconductor film provided around the third core insulating film and penetrating the first stacked film in the first direction, a first tunnel insulating film provided around the first channel semiconductor film and penetrating the first stacked film in the first direction, a first charge storage film provided around the first tunnel insulating film and penetrating the first stacked film in the first direction, a second stacked film in which a plurality of second conductive layers and a plurality of second insulating layers are alternately stacked one on top of another in a first direction and extend in the second and third directions, a fourth core insulating film penetrating the second stacked film in the first direction and containing an oxide, a second channel semiconductor film provided around the fourth core insulating film and penetrating the second stacked film in the first direction, a second tunnel insulating film provided around the second channel semiconductor film and penetrating the second stacked film in the first direction, and a second charge storage film provided around the second tunnel insulating film and penetrating the second stacked film in the first direction.

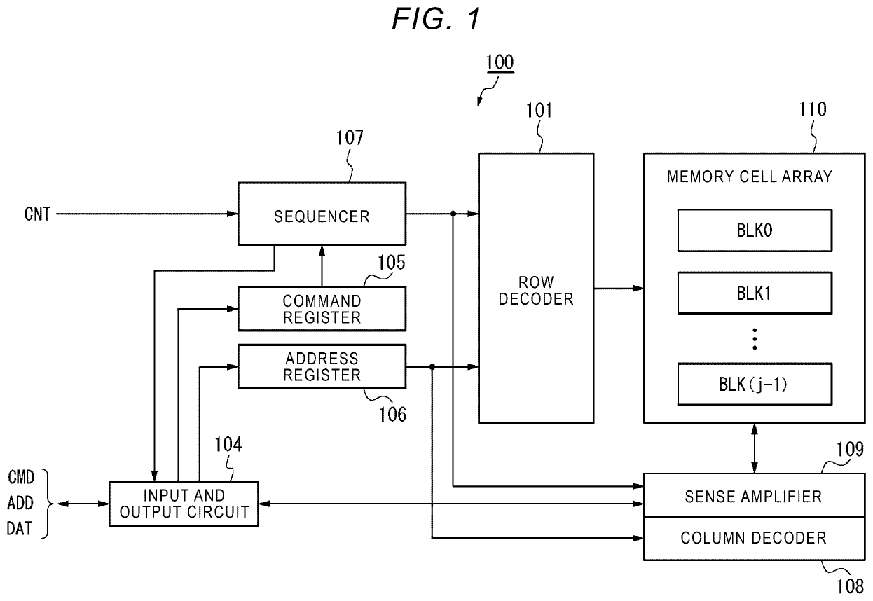

The overall configuration of a semiconductor memory device 100 will be described. The semiconductor memory device 100 according to this embodiment is, for example, a NAND-type flash memory capable of storing data in a non-volatile manner. FIG. 1 is a block diagram of the semiconductor memory device 100 according to this embodiment.

The semiconductor memory device 100 includes a memory cell array 110, a row decoder 101, a column decoder 108, a sense amplifier 109, an input and output circuit 104, a command register 105, an address register 106, and a sequencer (control circuit) 107.

The memory cell array 110 includes j blocks BLK0 to BLK (j−1). j is an integer greater than or equal to 2. Each of the blocks BLKs includes a plurality of memory cell transistors. The memory cell transistors include electrically rewritable memory cells. The memory cell array 110 includes a plurality of bit lines, a plurality of word lines, a source line, and the like in order to control a voltage applied to the memory cell transistors. A specific configuration of the block BLK will be described below.

The row decoder 101 receives a row address from the address register 106 and decodes the row address. The row decoder 101 selects a word line, and the like, based on the decoded row address. The row decoder 101 then transfers a plurality of voltages necessary for a write operation, a read operation, and an erase operation to the memory cell array 110.

The column decoder 108 receives a column address from the address register 106 and decodes the column address. The column decoder 108 performs a bit line selection operation based on the decoded column address.

The sense amplifier 109 detects and amplifies data read from the memory cell transistor connected to the bit line during the read operation. The sense amplifier 109 also performs operations to store write data in the memory cell transistor connected to the bit line during the write operation.

The input and output circuit 104 is connected to an external device (e.g., host device) via a plurality of input and output lines (DQ lines). The input and output circuit 104 receives a command CMD and an address ADD from the external device. The command CMD received by the input and output circuit 104 is sent to the command register 105. The address ADD received by the input and output circuit 104 is sent to the address register 106. The input and output circuit 104 also transmits and receives data DAT to and from the external device.

The sequencer 107 receives a control signal CNT from the external device. The control signal CNT includes a chip enable signal CEn, a command latch enable signal CLE, an address latch enable signal ALE, a write enable signal WEn, and a read enable signal REn. The “n” added to the signal name indicates active low. The sequencer 107 controls an operation of the entire semiconductor memory device 100 based on the command CMD stored in the command register 105 and the control signal CNT.

Next, an electrical configuration of the memory cell array 110 will be described.

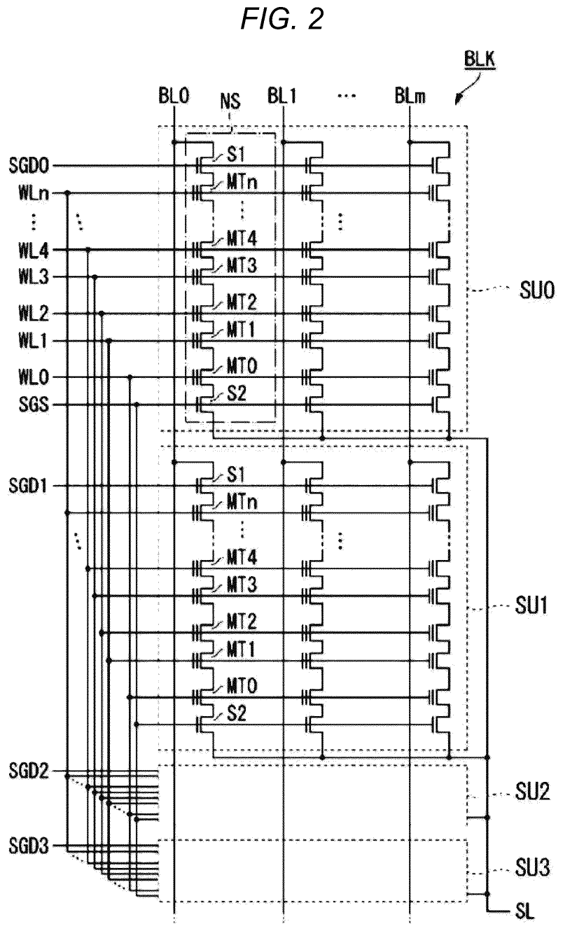

FIG. 2 is a diagram illustrating an equivalent circuit of a part of the memory cell array 110. FIG. 2 illustrates one block BLK of the memory cell array 10. The block BLK includes a plurality of (for example, four) string units SU0 to SU3.

Each of string units SU0 to SU3 is a collection of a plurality of NAND strings NS. One end of each NAND string NS is connected to one of bit lines BL0 to BLm (m is an integer greater than or equal to 1). The other end of the NAND string NS is connected to a source line SL. Each NAND string NS includes a plurality of memory cell transistors MT0 to MTn (n is an integer greater than or equal to 1), a first select transistor S1, and a second select transistor S2.

The plurality of memory cell transistors MT0 to MTn are electrically connected in series with each other. A memory cell transistor MT includes a control gate and a memory film (for example, a charge storage film), and stores data in a non-volatile manner. The memory cell transistor MT changes a state of the memory film in response to a voltage applied to the control gate. For example, the memory cell transistor MT stores charge in the charge storage film. A control gate of the memory cell transistor MT is connected to one of the corresponding word lines WL0 to WLn. The memory cell transistor MT is electrically connected to the row decoder 11 via the word line WL.

A first select transistor S1 in each NAND string NS is connected between the memory cell transistors MT0 to MTn and one of the bit lines BL0 to BLm. A drain of the first select transistor S1 is connected to one of the bit lines BL0 to BLm. A source of the first select transistor S1 is connected to the memory cell transistor MTn. A control gate of the first select transistor S1 in each NAND string NS is connected to one of first select gate lines SGD0 to SGD3. The first select transistor S1 is electrically connected to the row decoder 11 via the first select gate line SGD. The first select transistor S1 connects the NAND string NS to the bit line BL when a predetermined voltage is applied to one of the first select gate lines SGD0 to SGD3.

A second select transistor S2 in each NAND string NS is connected between the memory cell transistors MT0 to MTn and the source line SL. A drain of the second select transistor S2 is connected to the memory cell transistor MT0. A source of the second select transistor S2 is connected to the source line SL. A control gate of the second select transistor S2 is connected to a second select gate line SGS. The second select transistor S2 is electrically connected to the row decoder 11 via the second select gate line SGS. The second select transistor S2 connects the NAND string NS to the source line SL when a predetermined voltage is applied to the second select gate line SGS.

The memory cell array 110 may have a circuit configuration other than that described above. For example, the number of string units SU in each block BLK, the number of memory cell transistors MT in each NAND string NS, and the number of first select transistors S1 and second select transistors S2 may be changed. Furthermore, the block BLK may include a first sub-block including memory cell transistors MT0 to MTk and a second sub-block including a plurality of memory cell transistors MTk+1 to MTn. The erase operation may be performed in units of blocks BLK, or may be performed per sub-block after dividing the block BLK into the first sub-block and the second sub-block. The NAND string NS may include one or more dummy transistors that are not used to store valid data.

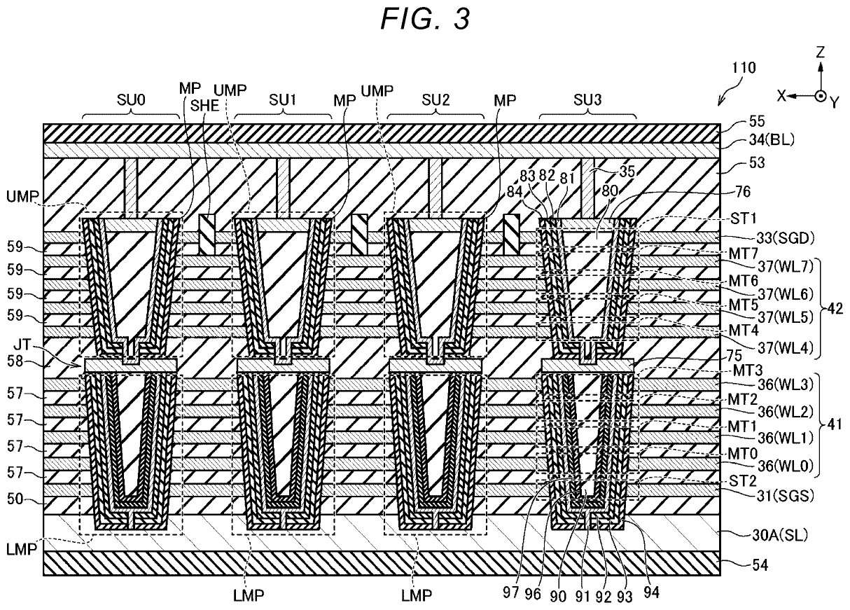

Next, a structure of the memory cell array 110 will be described with reference to FIG. 3. FIG. 3 illustrates an example of a cross-sectional structure of the memory cell array 110 of the semiconductor memory device 1 according to the embodiment.

In the drawings referred to below, the X-direction (an example of a first direction) corresponds to an extension direction of the bit line BL, and the Y-direction (an example of a second direction) corresponds to an extension direction of the word line WL. The Z-direction (an example of a third direction) corresponds to a direction from the insulating layer 54 of the semiconductor memory device 1 toward the bit line BL. In the following description, a surface and an end of a certain component on the insulating layer 54 side are referred to as a first surface and a first end, respectively. In addition, a surface and an end of a certain component on the bit line BL side are referred to as a second surface and a second end, respectively.

The memory cell array 110 includes conductive layers 30A, 31, 33, 34, and 35, a plurality of first conductive layers 36, a plurality of second conductive layers 37, insulating layers 50, 53, and 58, a plurality of first insulating layers 57, a plurality of second insulating layers 59, and a plurality of memory pillars MP. In FIG. 3, four memory pillars MP among the plurality of memory pillars MP are shown. In addition, in FIG. 3, a case where four first conductive layers 36 and four second conductive layers 37 are included as the plurality of first conductive layers 36 and the plurality of second conductive layers 37 is illustrated. In FIG. 3, a case where four memory cell transistors MT0 to MT3 are provided in the first sub-block and four memory cell transistors MT4 to MT7 are provided in the second sub-block is illustrated. In FIG. 3, a case where four first insulating layers 57 and four second insulating layers 59 are provided as the plurality of first insulating layers 57 and the plurality of second insulating layers 59 is illustrated.

The conductive layer 30A is formed, for example, in a plate shape extending along the XY plane. The conductive layer 30A is used as the source line SL. The conductive layer 30A is made of a conductive material. The conductive material includes, for example, an N-type semiconductor material with impurities or metal.

An insulating layer 50 is provided on a second surface of the conductive layer 30A. A conductive layer 31 is provided on a second surface of the insulating layer 50. The conductive layer 31 extends in the X-direction and the Y-direction, for example, and has a plate-like shape extending along the XY plane. The conductive layer 31 is used as the second select gate line SGS. The conductive layer 31 contains tungsten or molybdenum and includes a barrier metal film around the tungsten or the molybdenum, for example.

On the second surface of the conductive layer 31, the first insulating layers 57 and the first conductive layers 36 are stacked alternately one on top of another in the Z-direction, in the order of the first insulating layer 57, the first conductive layer 36, . . . , the first insulating layer 57, and the first conductive layer 36. The first conductive layers 36 and the first insulating layers 57 each have, for example, a plate-like shape that extends in the X-direction and the Y-direction and spreads along the XY plane. The four first conductive layers 36 are used as the word lines WL0 to WL3 in order from the conductive layer 31 side along the Z-direction. The first conductive layers each 36 contain tungsten or molybdenum and include a barrier metal film covering the tungsten or the molybdenum, for example.

An insulating layer 58 has, for example, a plate-like shape extending in the X-direction and the Y-direction and spreading along the XY plane.

On the second surface of the first conductive layer 36 used as the word line WL3, the insulating layer 58 is stacked. On a second surface of the insulating layer 58, the second conductive layers 37 and second insulating layers 59 are stacked alternately one on top of another in the Z-direction, in the order of the second conductive layer 37, the second insulating layer 59, . . . , the second conductive layer 37, and the second insulating layer 59. The second conductive layer 37 and the second insulating layer 59 have, for example, a plate-like shape extending in the X-direction and the Y-direction and spreading along the XY plane. The four second conductive layers 37 are used as word lines WL4 to WL7 in order from the conductive layer 31 side along the Z-direction. The second conductive layers 37 each contain tungsten or molybdenum and include a barrier metal film covering the tungsten or the molybdenum, for example.

A first stacked film 41 includes a plurality of first conductive layers 36 and a plurality of first insulating layers 57.

A second stacked film 42 includes the plurality of second conductive layers 37 and the plurality of second insulating layers 59.

A conductive layer 33 is stacked on the second surface of the second conductive layer 37 used as the word line WL7, with the second insulating layer 59 interposed therebetween. The conductive layer 33 is formed, for example, in a plate shape extending in the X-direction and the Y-direction and spreading along the XY plane. The conductive layer 33 is used as the first select gate line SGD. The conductive layer 33 contains tungsten or molybdenum and includes a barrier metal film around the tungsten or the molybdenum, for example. The conductive layer 33 is electrically insulated for each string unit SU, for example, by a plurality of members SHE.

An insulating layer 53 is stacked on the second surface of the conductive layer 33. A conductive layer 34 is stacked on a second surface of the insulating layer 53. The conductive layer 34 is provided extending along the X-direction. The conductive layer 34 functions as the bit line BL.

A stacked structure including the conductive layers 30A, 31, 33, and 34, the first conductive layers 36, the second conductive layers 37, the insulating layers 50, 53, and 58, the first insulating layers 57, and the second insulating layers 59 is surrounded by an insulating layer. In FIG. 3, the insulating layer 54 in contact with the first surface of the conductive layer 30A and the insulating layer 55 in contact with the second surface of the conductive layer 34 are shown.

A plurality of memory pillars MP are provided extending along the Z-direction. The plurality of memory pillars MP penetrate the conductive layer 31, the first conductive layers 36, the second conductive layers 37, the conductive layer 33, the insulating layer 50, the first insulating layers 57, the insulating layer 58, and the second insulating layers 59. Each of the plurality of memory pillars MP functions as one NAND string NS.

Each memory pillar MP has a lower memory pillar LMP, an upper memory pillar UMP, and a joint JT provided between the lower memory pillar LMP and the upper memory pillar UMP to join (connect) the lower memory pillar LMP and the upper memory pillar UMP.

The lower memory pillar LMP has a portion whose diameter or cross-sectional area increases from the insulating layer 54 side toward the insulating layer 55 side or toward the Z-direction. The upper memory pillar UMP has a portion whose diameter or cross-sectional area increases from the insulating layer 54 side toward the insulating layer 55 side or toward the Z-direction.

Each lower memory pillar LMP includes a first core insulating film 90, a second core insulating film 96, a third core insulating film 97, a first channel semiconductor film 91, a first tunnel insulating film 92, a first charge storage film 93, and a first block insulating film 94.

The first core insulating film 90 penetrates the first stacked film 41 in the Z-direction. The first core insulating film 90 contains an oxide. Here, the oxide is, for example, a compound containing silicon and oxygen covalent bonded.

The second core insulating film 96 is provided around the first core insulating film 90. The second core insulating film 96 penetrates the first stacked film 41 in the Z-direction. The second core insulating film 96 contains a nitride. Here, the nitride is, for example, a compound containing silicon and nitrogen covalent bonded.

The third core insulating film 97 is provided around the second core insulating film 96. The third core insulating film 97 penetrates the first stacked film 41 in the Z-direction. The third core insulating film 97 contains an oxide. Here, the oxide is, for example, a compound containing silicon and oxygen covalent bonded.

The first channel semiconductor film 91 is provided around the third core insulating film 97. The first channel semiconductor film 91 penetrates the first stacked film 41 in the Z-direction. The first channel semiconductor film 91 functions as a current path (channel) of the lower memory pillar LMP. The first channel semiconductor film 91 contains, for example, a semiconductor material such as polysilicon.

The first tunnel insulating film 92 is provided around the first channel semiconductor film 91. The first tunnel insulating film 92 is an insulating film that has insulating properties, but allows a current to pass therethrough when a predetermined voltage is applied across it. The first tunnel insulating film 92 contains, for example, an oxide. Here, the oxide is, for example, a compound containing silicon and oxygen covalent bonded.

The first charge storage film 93 is provided around the first tunnel insulating film 92. The first charge storage film 93 is a film containing a material capable of storing charges. The first charge storage film 93 contains, for example, a nitride. Here, the nitride is, for example, a compound containing silicon and nitrogen covalent bonded.

The first block insulating film 94 is provided around the first charge storage film 93. The first block insulating film 94 is a film that prevents the flow of charges between the first charge storage film 93 and the plurality of first conductive layers 36. The first block insulating film 94 contains, for example, an oxide. Here, the oxide is, for example, a compound of silicon and oxygen covalent bonded.

A portion where each of the lower memory pillars LMP intersects with the conductive layer 31 functions as a select transistor ST2. A portion where each of the lower memory pillars LMP intersects with each first conductive layers 36 functions as the memory cell transistor MT.

Each of the upper memory pillars UMP includes a fourth core insulating film 80, a second channel semiconductor film 81, a second tunnel insulating film 82, a second charge storage film 83, and a second block insulating film 84.

The fourth core insulating film 80 penetrates the second stacked film 42 in the Z-direction. The fourth core insulating film 80 contains an oxide. Here, the oxide is, for example, a compound of silicon and oxygen covalent bonded.

The second channel semiconductor film 81 is provided around the fourth core insulating film 80. The second channel semiconductor film 81 penetrates the second stacked film 42 in the Z-direction. The second channel semiconductor film 81 functions as a current path (channel) of the upper memory pillar UMP. The second channel semiconductor film 81 contains, for example, a semiconductor material such as polysilicon.

The second tunnel insulating film 82 is provided around the second channel semiconductor film 81. The second tunnel insulating film 82 is an insulating film that has insulating properties, but allows a current to pass therethrough when a predetermined voltage is applied across it. The second tunnel insulating film 82 contains, for example, an oxide. Here, the oxide is, for example, a compound of silicon and oxygen covalent bonded.

The second charge storage film 83 is provided around the second tunnel insulating film 82. The second charge storage film 83 is a film that includes a material capable of storing charges. The second charge storage film 83 contains, for example, a nitride. Here, the nitride is, for example, a compound of silicon and nitrogen covalent bonded.

The second block insulating film 84 is provided around the second charge storage film 83. The second block insulating film 84 is a film that prevents charges from flowing between the second charge storage film 83 and the plurality of second conductive layers 37. The second block insulating film 84 contains, for example, an oxide. Here, the oxide is, for example, a compound of silicon and oxygen covalent bonded.

A portion where each of the upper memory pillars UMP intersects with each second conductive layers 37 functions as the memory cell transistor MT. A portion where each of the upper memory pillars UMP intersects with the conductive layer 33 functions as a select transistor ST1.

A conductive member 76 is provided on the fourth core insulating film 80 of the upper memory pillar UMP. The conductive member 76 contains, for example, polysilicon.

The joint JT is provided in the insulating layer 58 and includes a conductive member 75. The conductive member 75 is electrically connected to the second channel semiconductor film 81. The conductive member 75 contains, for example, polysilicon.

The conductive layer 34 and the conductive member 76 are electrically connected to each other by a conductive member 35. The conductive member 35 contains, for example, polysilicon.

The insulating layers 50, 53, 58, and 60, the plurality of first insulating layers 57, and the plurality of second insulating layers 59 contain, for example, an oxide. Here, the oxide contains, for example, an insulator such as a compound of silicon and oxygen covalent bonded.

The lower memory pillar LMP may be disposed on the second surface side, and the upper memory pillar UMP may be disposed on the first surface side. In other words, the memory pillar MP including the second core insulating film 96 and the third core insulating film 97 may be disposed on the second surface side, and the memory pillar MP not including the second core insulating film 96 and the third core insulating film 97 may be disposed on the first surface side.

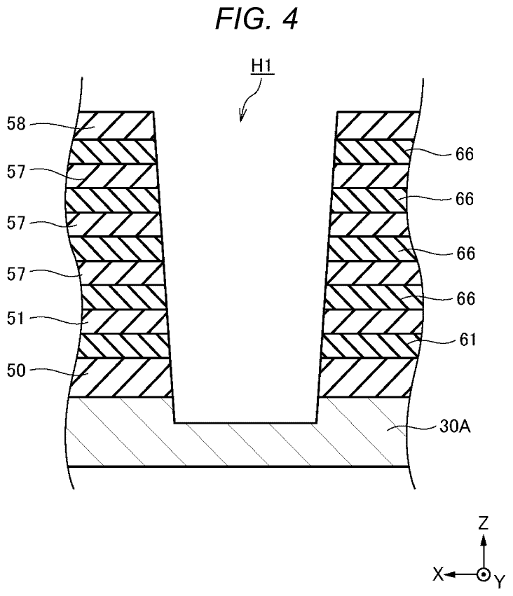

FIGS. 4 to 10 are schematic cross-sectional views illustrating a method of manufacturing the semiconductor memory device of this embodiment.

For example, by a chemical vapor deposition (CVD) method, an insulating layer 50 containing an oxide and a sacrificial layer 61 containing a nitride are formed in this order on a second surface side of a conductive layer 30A. Next, on a second surface side of the sacrificial layer 61, a plurality of first insulating layers 57 containing an oxide and a plurality of sacrificial layers 66 containing a nitride are alternately formed by stacking one layer on top of another layer in this order. Next, an insulating layer 58 containing an oxide is formed on a second surface side of the sacrificial layer 66.

Next, by a reactive ion etching (RIE) method, for example, an opening H1 (through-hole) is formed that penetrates an insulating layer 50, first insulating layers 57, the insulating layer 58, the sacrificial layer 61, and the sacrificial layers 66 in the Z-direction, extends in the Z-direction, and reaches the conductive layer 30A (FIG. 4).

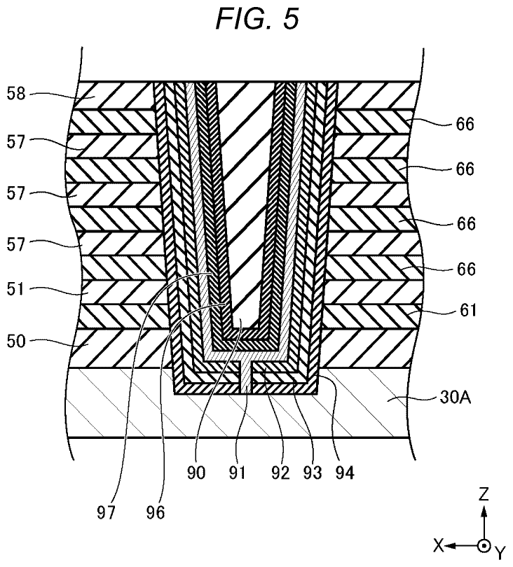

Next, a first block insulating film 94, a first charge storage film 93, and a first tunnel insulating film 92 are formed in order within the opening H1, for example, by an atomic layer deposition (ALD) method. Next, a hole penetrating the first tunnel insulating film 92, the first charge storage film 93, and the first block insulating film 94 is formed at the bottom of the opening H1, for example, by the RIE. Next, the first channel semiconductor film 91 is formed inside the hole and on a second surface side of the first tunnel insulating film 92, for example, by the ALD. Next, the third core insulating film 97, the second core insulating film 96, and the first core insulating film 90 are formed in this order on a second surface side of the first channel semiconductor film 91, for example, by the ALD (FIG. 5).

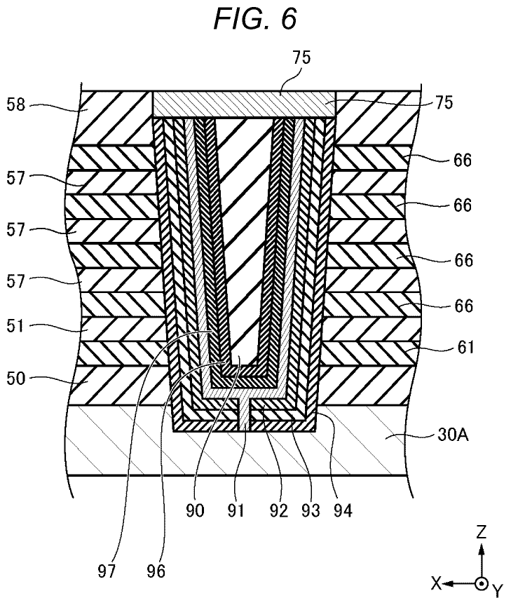

Next, using a photoresist (not shown) as a mask, the first block insulating film 94, the first charge storage film 93, the first tunnel insulating film 92, the first channel semiconductor film 91, the third core insulating film 97, the second core insulating film 96, and the first core insulating film 90 on the second surface side are partially removed by, for example, the RIE method. Next, a conductive member 75 is formed by, for example, the CVD method in a portion where the first block insulating film 94, the first charge storage film 93, the first tunnel insulating film 92, the first channel semiconductor film 91, the third core insulating film 97, the second core insulating film 96, and the first core insulating film 90 are partially removed. Next, the photoresist (not shown) is removed (FIG. 6).

Next, an insulating layer is formed on the second surface side of the insulating layer 58 and the conductive member 75 by, for example, the CVD method, a film thickness of the insulating layer 58 in the Z-direction is increased, and a conductive member 75 is disposed inside the insulating layer 58. Next, a plurality of sacrificial layers 67 containing nitride and a plurality of second insulating layers 59 containing oxide are alternately formed by stacking one layer on top of another layer in order on a second surface side of the insulating layer 58. Next, an insulating layer 60, a sacrificial layer 63 and an insulating layer 53 are formed in order on a second surface side of a sacrificial layer 67.

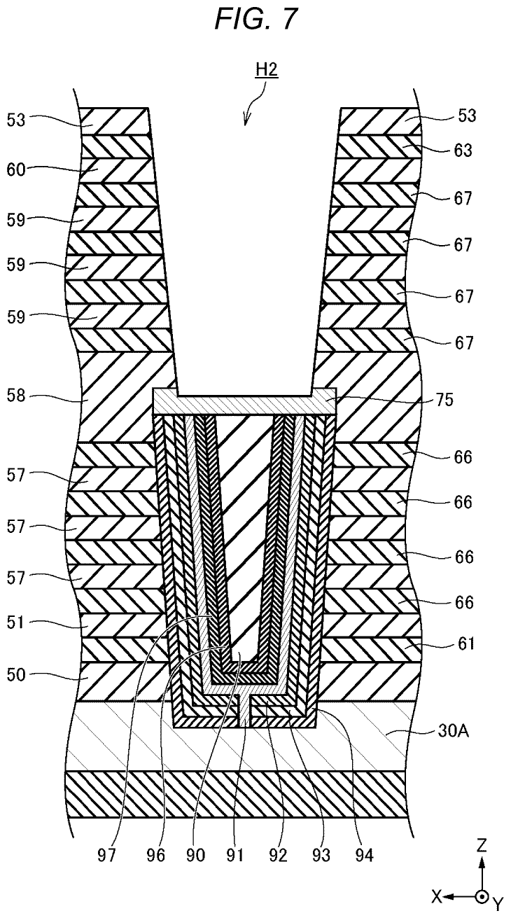

Next, for example, by the RIE method, an opening H2 (through hole) that penetrates the insulating layer 58, the multiple sacrificial layers 67, the second insulating layers 59, the insulating layer 60, the sacrificial layer 63, and the insulating layer 53 in the Z-direction, extends in the Z-direction, and reaches the conductive member 75, is formed (FIG. 7).

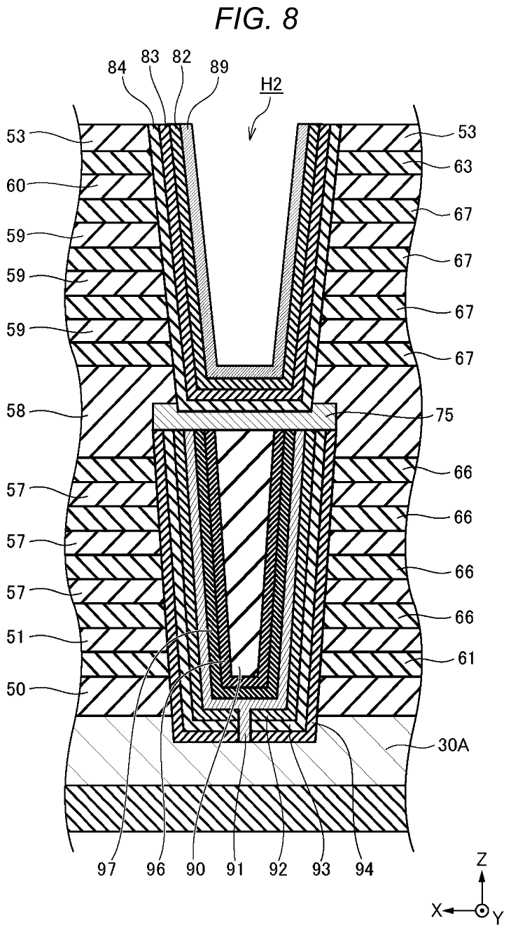

Next, a second block insulating film 84, a second charge storage film 83, a second tunnel insulating film 82, and a protective film 89 are formed in order in the opening H2, for example, by the ALD method. Here, the protective film 89 contains, for example, amorphous silicon (FIG. 8).

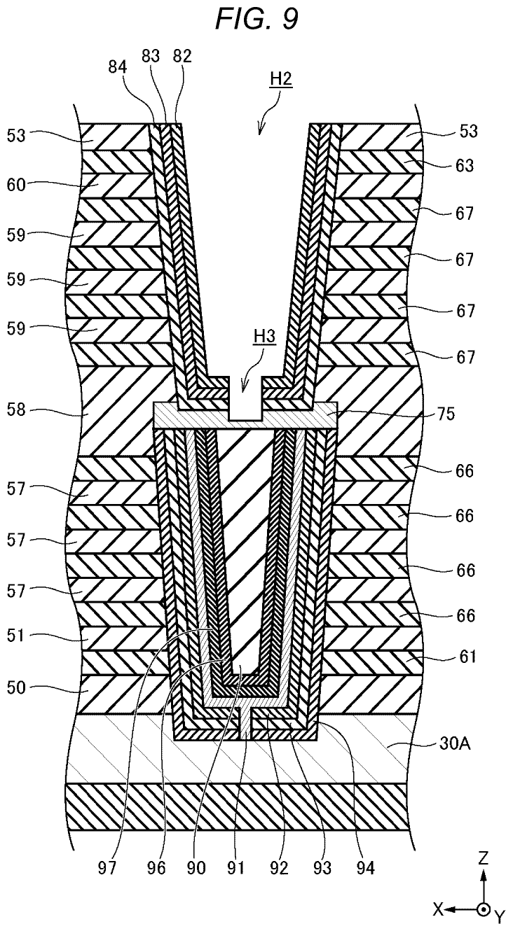

Next, an opening H3 (through-hole) is formed at a lower part of the opening H2 that penetrates the second tunnel insulating film 82, the second charge storage film 83, the second block insulating film 84, and the protective film 89 and reaches the conductive member 75, for example, by the RIE method. Next, the protective film 89 is removed, for example, by wet etching or the like (FIG. 9).

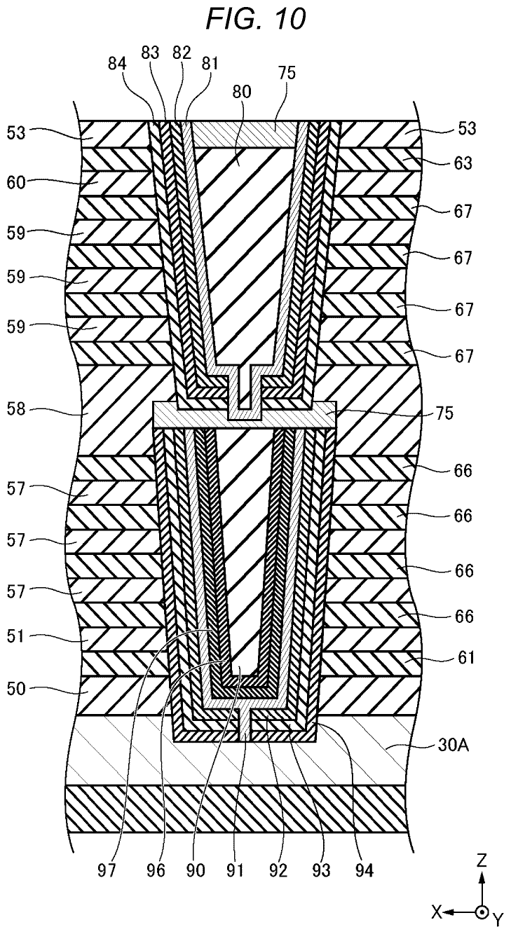

Next, a second channel semiconductor film 81 is formed in the opening H2 by, for example, the ALD method. Next, a fourth core insulating film 80 is formed in the opening H2 by, for example, the CVD method. Next, a conductive member 75 is formed on the fourth core insulating film 80 by, for example, the CVD method (FIG. 10).

Next, replacement of the sacrificial layer 61 with the conductive layer 31, the sacrificial layers 66 with the first conductive layers 36, the sacrificial layers 67 with the second conductive layers 37, and the sacrificial layer 63 with the conductive layer 33 are performed. For example, the sacrificial layers 61, 66, 67, and 63 are removed by wet etching using phosphoric acid (H₃PO₄) through an opening (not shown). Next, the conductive layer 31, the first conductive layers 36, the second conductive layers 37, and the conductive layer 33, each of which contains tungsten (W) or molybdenum (Mo) and includes a barrier metal film covering the tungsten or the molybdenum, are formed by, for example, the CVD method.

Next, the insulating layer 53, a member SHE, the conductive member 35, the conductive layer 34, and the insulating layer 55 are formed as appropriate to obtain the semiconductor memory device 100 of this embodiment.

Next, the effects of the semiconductor memory device of this embodiment will be described.

A memory capacity of the semiconductor memory device is increased by performing multi-bit value recording in the memory cell transistor MT. Here, in order to be able to store more information in one memory cell transistor MT, it is preferable that a larger number of threshold voltages Vt can be set by allowing a larger number of electrons to be stored in the charge storage film of the memory cell transistor MT.

For example, consider a triple-level cell (TLC) method in which the distribution of threshold voltages of the memory cell transistor MT is divided into 8 parts, and a quad-level cell (QLC) method in which the distribution of the threshold voltages of the memory cell transistor MT is divided into 16 parts. In this case, a threshold voltage Vt of “S15” level, which has the highest threshold voltage Vt in the QLC method, is higher than a threshold voltage Vt of “G” level, which has the highest threshold voltage Vt in the TLC method. As a result, in the QLC method, more threshold voltages Vt can be set than in the TLC method, and the storage capacity of the semiconductor memory device can be increased.

However, when attempting to inject more electrons into the charge storage film, there is a problem in that the injected electrons cannot be retained in the charge storage film because they may leak out. When the thickness of the charge storage film and the tunnel insulating film are made different for each memory cell transistor MT in order to prevent the leakage of electrons from the charge storage film, there is a problem that manufacturing becomes difficult because it takes a lot of time to set process conditions for the semiconductor memory device.

Therefore, the semiconductor memory device of this embodiment includes a first core insulating film that penetrates the first stacked film in a first direction and contains an oxide, a second core insulating film that is provided around the first core insulating film, penetrates the first stacked film in the first direction, and contains a nitride, and a third core insulating film that is provided around the second core insulating film, penetrates the first stacked film in the first direction, and contains an oxide.

Electrons that are migrated from the charge storage film to the channel semiconductor film during the erase operation are trapped in the second core insulating film that contains a nitride. As a result, for example, in the QLC method, by trapping electrons in the second core insulating film containing a nitride, not only the “S0” level but also the “S1” level can have a threshold voltage distribution in which the threshold voltage Vt is lower than the ground voltage. In other words, the neutral threshold voltage Vt of the threshold voltage can be changed from between “S0” level and “S1” to between “S1” level and “S2” level, for example. Therefore, at “S15” level where the threshold voltage is the highest, the amount of electrons injected into the charge storage film can be reduced. As a result, for example, the threshold voltage Vt of “S15” level of the QLC method can be brought closer to the threshold voltage Vt of the “G” level of the TLC method. The threshold voltage Vt of “S0” level of the QLC method based on the ground voltage is lower than the threshold voltage Vt of “S0” level of the TLC method based on the ground voltage.

Then, in a semiconductor memory device including a charge storage layer manufactured under the same process conditions, the memory pillar that does not include the second core insulating film and the third core insulating film can be used as a memory cell transistor MT and memory cell of the TLC method, and the memory pillar MP that includes the second core insulating film and the third core insulating film can be used as a memory cell transistor MT and memory cell of the QLC method.

As a result, even when the amount of electrons stored in the charge storage film is small, many threshold voltages Vt can be set.

According to the method of manufacturing the semiconductor memory device of this embodiment, a semiconductor memory device that is easy to manufacture and capable of high-density recording can be provided.

### Second Embodiment

A semiconductor memory device of this embodiment differs from the semiconductor memory device of the first embodiment in that the first stacked film and the second stacked film are arranged side by side in the second direction. Here, the description of the contents that overlap with the first embodiment will be omitted.

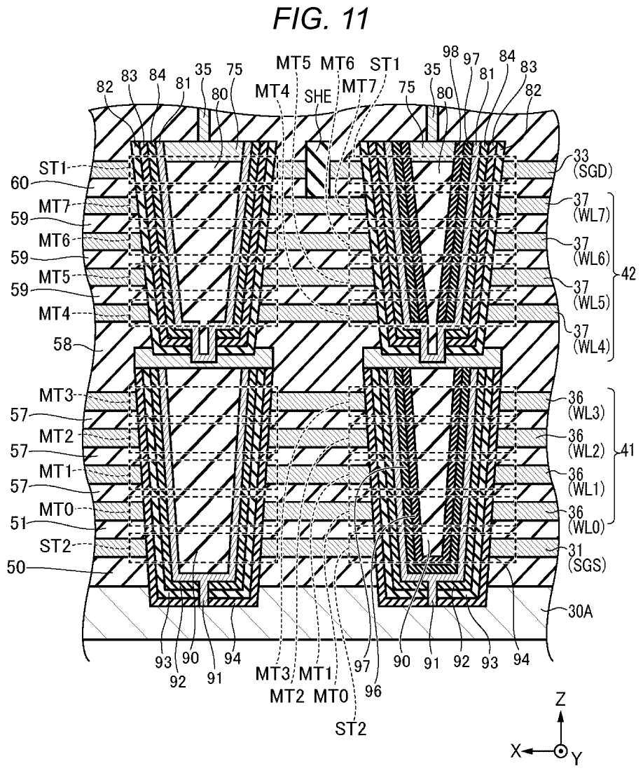

FIG. 11 is a schematic cross-sectional view of the semiconductor memory device according to this embodiment. A memory pillar and a stacked film including a second core insulating film and a third core insulating film, and a memory pillar and a stacked film not including the second core insulating film and the third core insulating film are arranged side by side in the X-direction. The memory pillar and the stacked film including the second core insulating film and the third core insulating film, and the memory pillar and the stacked film not including the second core insulating film and the third core insulating film also may be arranged side by side in the Y-direction.

Even by the method of manufacturing the semiconductor memory device of this embodiment, it is possible to provide a semiconductor memory device that is easy to manufacture and capable of high-density recording.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a first stacked film in which a plurality of first conductive layers and a plurality of first insulating layers are alternately stacked one on top of another in a first direction and extend in a second direction intersecting the first direction and a third direction intersecting the first direction and the second direction;
a first core insulating film penetrating the first stacked film in the first direction and containing an oxide;
a second core insulating film provided around the first core insulating film, penetrating the first stacked film in the first direction, and including a nitride;
a third core insulating film provided around the second core insulating film, penetrating the first stacked film in the first direction, and containing an oxide;
a first channel semiconductor film provided around the third core insulating film and penetrating the first stacked film in the first direction;
a first tunnel insulating film provided around the first channel semiconductor film and penetrating the first stacked film in the first direction;
a first charge storage film provided around the first tunnel insulating film and penetrating the first stacked film in the first direction;
a second stacked film in which a plurality of second conductive layers and a plurality of second insulating layers are alternately stacked one on top of another in a first direction and extend in the second and third directions;
a fourth core insulating film penetrating the second stacked film in the first direction and containing an oxide;
a second channel semiconductor film provided around the fourth core insulating film and penetrating the second stacked film in the first direction;
a second tunnel insulating film provided around the second channel semiconductor film and penetrating the second stacked film in the first direction; and
a second charge storage film provided around the second tunnel insulating film and penetrating the second stacked film in the first direction.

2. The semiconductor memory device according to claim 1, wherein
the first stacked film and the second stacked film are arranged along the first direction, and
the first channel semiconductor film is electrically connected to the second channel semiconductor film.

3. The semiconductor memory device according to claim 2, wherein the first stacked film is arranged below the second stacked film in the first direction.

4. The semiconductor memory device according to claim 1, wherein
the first stacked film and the second stacked film are arranged side by side in the second direction.

5. The semiconductor memory device according to claim 1, wherein
a portion of the first charge storage film provided between the first conductive layer and the first channel semiconductor film functions as a first memory cell that stores first data, and
a portion of the second charge storage film provided between the second conductive layer and the second channel semiconductor film functions as a second memory cell that stores second data having a number of bits less than the first data.

6. The semiconductor memory device according to claim 1, wherein
after an erase operation performed on memory cells that are along the first channel semiconductor film, electrons are trapped in the second core insulating film.

7. The semiconductor memory device according to claim 1, wherein
after an erase operation performed on first memory cells that are along the first channel semiconductor film and second memory cells that are along the second channel semiconductor film, threshold voltages of the first memory cells based on a ground voltage are lower than threshold voltages of the second memory cells based on the ground voltage.

8. The semiconductor memory device according to claim 7, further comprising:
a control circuit configured to perform a write operation on the first memory cells to program the first memory cells to one of 2^{N1} threshold voltage levels, and on the second memory cells to program the second memory cells to one of 2^{N2} threshold voltage levels, where N2<N1.

9. The semiconductor memory device according to claim 8, wherein N1=4 and N2=3.

10. A method of manufacturing a semiconductor memory device, said method comprising:
forming a first stacked film in which a plurality of first sacrificial layers and a plurality of first insulating layers are alternately stacked one on top of another in a first direction and extend in a second direction intersecting the first direction and a third direction intersecting the first direction and the second direction;
forming a first hole through the first stacked film;
forming a first block insulating film, a first charge storage film, a first tunnel insulating film, a first channel semiconductor film, and a stack of three first core insulating films in order from an inner surface of the first hole;
removing the first sacrificial layers and depositing first conductive layers at locations where the first sacrificial layers have been removed;
forming a second stacked film in which a plurality of second sacrificial layers and a plurality of second insulating layers are alternately stacked one on top of another in the first direction and extend in a second direction intersecting the first direction and a third direction intersecting the first direction and the second direction;
forming a second hole through the second stacked film;
forming a second block insulating film, a second charge storage film, a second tunnel insulating film, a second channel semiconductor film, and a second core insulating film in order from an inner surface of the second hole; and
removing the second sacrificial layers and depositing second conductive layers at locations where the second sacrificial layers have been removed.

11. The method according to claim 10, wherein
the first stacked film and the second stacked film are arranged along the first direction, and
the first channel semiconductor film is electrically connected to the second channel semiconductor film.

12. The method according to claim 11, wherein the first stacked film is arranged below the second stacked film in the first direction.

13. The method according to claim 10, wherein
the first stacked film and the second stacked film are arranged side by side in the second direction.

14. A method of performing operations in a semiconductor memory device comprising:
a first stacked film in which a plurality of first conductive layers and a plurality of first insulating layers are alternately stacked one on top of another in a first direction and extend in a second direction intersecting the first direction and a third direction intersecting the first direction and the second direction;
a first core insulating film penetrating the first stacked film in the first direction and containing an oxide;
a second core insulating film provided around the first core insulating film, penetrating the first stacked film in the first direction, and including a nitride;
a third core insulating film provided around the second core insulating film, penetrating the first stacked film in the first direction, and containing an oxide;
a first channel semiconductor film provided around the third core insulating film and penetrating the first stacked film in the first direction;
a first tunnel insulating film provided around the first channel semiconductor film and penetrating the first stacked film in the first direction;
a first charge storage film provided around the first tunnel insulating film and penetrating the first stacked film in the first direction;
a second stacked film in which a plurality of second conductive layers and a plurality of second insulating layers are alternately stacked one on top of another in a first direction and extend in the second and third directions;
a fourth core insulating film penetrating the second stacked film in the first direction and containing an oxide;
a second channel semiconductor film provided around the fourth core insulating film and penetrating the second stacked film in the first direction;
a second tunnel insulating film provided around the second channel semiconductor film and penetrating the second stacked film in the first direction; and
a second charge storage film provided around the second tunnel insulating film and penetrating the second stacked film in the first direction, wherein a write operation performed on first memory cells that are along the first channel semiconductor film and second memory cells that are along the second channel semiconductor film, comprises the steps of:
programming the first memory cells to one of 2^{N1} threshold voltage levels; and
programming the second memory cells to one of 2^{N2} threshold voltage levels, where N2<N1.

15. The method according to claim 14, wherein N1=4 and N2=3.

16. The method according to claim 14, further comprising:
prior to the write operation, performing an erase operation on the first memory cells and the second memory cells, wherein
after the erase operation and before the write operation, threshold voltages of the first memory cells based on a ground voltage are lower than threshold voltages of the second memory cells based on the ground voltage.

17. The method according to claim 16, wherein electrons are trapped in the second core insulating film during the erase operation.

18. The method according to claim 14, wherein
the first stacked film and the second stacked film are arranged along the first direction, and
the first channel semiconductor film is electrically connected to the second channel semiconductor film.

19. The method according to claim 18, wherein the first stacked film is arranged below the second stacked film in the first direction.

20. The method according to claim 14, wherein
the first stacked film and the second stacked film are arranged side by side in the second direction.
